(19) United States
(12) Patent Application Publication
(10) Pub. No.: US 2010/0237452 A1
(43) Pub. Date: Sep. 23, 2010

(54) SEMICONDUCTOR DEVICE AND BACKSIDE ILLUMINATION SOLID-STATE IMAGING DEVICE

(76) Inventors: Kenichiro HAGIWARA, Yokohama-shi (JP); Ikuko INOUE, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/725,549

(22) Filed: Mar. 17, 2010

(30) Foreign Application Priority Data
Mar. 18, 2009 (JP) 2009-066637

(51) Int. Cl. H01L 31/02; H01L 31/18; H01L 31/0232

(52) U.S. Cl. 257/432; 257/460; 438/98; 257/452; 257/E31.113; 257/E31.127; 257/E31.11

(57) ABSTRACT

A semiconductor substrate has a first principal face and a second principal face opposite thereto. A pixel unit, an analog circuit and a digital circuit are formed in a first, second and third region of the semiconductor substrate. An interconnect is formed on each of the first and second principal faces of the second region. A plurality of penetrative electrodes is formed in the semiconductor substrate to penetrate the first and second principal faces. These penetrative electrodes are electrically connected with interconnects formed in the first and second principal faces of the second region. A guard ring is formed in the semiconductor substrate to penetrate the first and second principal faces, the guard ring is surrounding the penetrative electrodes.

### CROSS-REFERENCE TO RELATED APPLICATIONS

This application is based upon and claims the benefit of priority from prior Japanese Patent Application No. 2009-066637, filed Mar. 18, 2009, the entire contents of which are incorporated herein by reference.

### BACKGROUND OF THE INVENTION

1. Field of the Invention

The present invention relates to a semiconductor device and a backside illumination solid-state imaging device, which are configured so that interconnects penetrate double faces of a semiconductor substrate.

2. Description of the Related Art

Various electronic apparatuses, for example, mobile pones are miniaturized year after year. Under such circumstances, the needs to miniaturize a semiconductor device used for the foregoing apparatuses become extremely high on the market. For this reason, an analog circuit and a high-speed signal processing circuit (mainly, digital circuit), which have been conventionally formed on an independent semiconductor chip, are integrated on one semiconductor chip. However, various problems arise with one-chip structure of the foregoing circuits. For example, a CMOS image sensor is configured so that an analog circuit and a digital circuit are formed together on one chip. As a result, miniaturization of a semiconductor chip is a factor of causing a noise problem between the foregoing circuit units. For this reason, conventionally, the well structure of a semiconductor substrate is suitably designed to solve the foregoing noise problem between the foregoing circuits. Specifically, a high-density impurity concentration P-type substrate (Pt-type substrate) is used as a semiconductor substrate, and then, an analog circuit is formed in a P-well on the P⁺-type substrate. In this way, the analog circuit is sufficiently grounded via the P⁺-type substrate. Moreover, in a digital circuit, an N-type epitaxial layer is interposed between the P⁺-type substrate and the P-well so that they are isolated. In this way, the digital circuit is isolated to solve the foregoing noise problem.

A solid-state imaging device such as a CMOS sensor is proposed to shift to a backside illumination type, which is adaptable for securing light incident on a photodiode, considering chip size miniaturization, that is, a narrowed pitch of pixels. An already-existing backside illumination solid-state imaging device has the following structure. According to the structure, light incident from a subject is radiated to a face opposite to the surface of a semiconductor substrate formed with circuit elements such as a transistor, that is, the rear thereof. In the backside illumination solid-state imaging device, a light illumination face, that is, the rear of the semiconductor substrate is upwardly mounted. For this reason, the rear of the semiconductor substrate must be formed with external terminals and product test terminals. So, penetrative electrodes are formed to penetrate double sides of a substrate. Interconnects and electrodes formed on the surface of the substrate are electrically connected to the external terminals and product test terminals on the rear thereof via the penetrative electrodes. In general, the following method is employed to form the penetrative electrodes used for the foregoing solid-state imaging device. For example, a semiconductor substrate (silicon substrate) is etched and an insulating film is formed thereon, and thereafter, a conductor is embedded. Thereafter, silicon is polished so that a thin film is formed. According to any methods of forming the penetrative electrodes, it is evident that the semiconductor substrate is thinned, and thereby, the penetrative electrodes are easily formed. Moreover, in a backside illumination CMOS image sensor, there is a need to thin the semiconductor substrate in view of securing light incident on a photodiode and preventing optical crosstalk. As described before, in a solid-state imaging device, a P⁺-type substrate is used as a semiconductor substrate. In this way, the P-well of an analog circuit is sufficiently grounded via the foregoing substrate. However, the substrate is thinned; for this reason, substrate resistance becomes high, and ground is insufficient. As a result, it is easy to receive the influence of noise.

Jpn. Pat. Appln. KOKAI Publication No. 2004-146816 (FIG. 3(B)) discloses a backside illumination solid-state imaging device having the following structure. According to the structure, an imaging chip is provided with Si penetrative electrodes so that the electrodes are led to the bottom surface. Further, bumps are provided so that the imaging chip is connected to an image processing chip. Moreover, Jpn. Pat. Appln. KOKAI Publication No. 2008-205256 discloses a backside illumination solid-state imaging device having the following structure. According to the structure, the surface of a peripheral unit on an image area is provided with n-well whose positive voltage is biased. In this way, unnecessary charges generated in the peripheral unit on an image area are speedy exhausted.

### BRIEF SUMMARY OF THE INVENTION

According to a first aspect of the present invention, there is provided a backside illumination solid-state imaging device comprising:

a semiconductor substrate having a first principal face and a second principal face opposite thereto, and including a pixel unit formed in a first region, an analog circuit formed in a second region and a digital circuit formed in a third region;

an interconnect formed on each of the first and second principal faces of the semiconductor substrate;

at least one penetrative electrode formed in the semiconductor substrate to penetrate the first and second principal faces, and electrically connecting the interconnects formed in the first and second principal faces of the semiconductor substrate; and

a guard ring formed in the semiconductor substrate to penetrate the first and second principal faces, and surrounding said at least one penetrative electrode.

According to a second aspect of the present invention, there is provided a method of manufacturing a backside illumination solid-state imaging device, comprising:

forming at least one first hole and a second hole with a depth in a semiconductor substrate, the semiconductor substrate has a first principal face and a second principal face opposite thereto, said at least one first hole is surrounded by the second hole, the depth does not reach the second principal face from the first principal face;

depositing a first insulating film on the entire surface with a thickness that said at least one first hole and the second hole are not filled with the first insulating film;

forming a conductor film on the entire surface with a thickness that at least one first hole and the second hole are not filled with the conductor film;

removing the conductor film and the first insulating film to expose the first principal face;

forming a first interconnect electrically connecting the conductor film remaining in said at least one first hole while forming a second interconnect the conductor film remaining in the second hole on the first principal face; and

polishing the semiconductor substrate from the second principal face to expose each surface of the conductor film remaining in said at least one first hole and the conductor film remaining in the second hole, and forming at least one penetrative electrode using the conductor film remaining in said at least one first hole while forming a guard ring surrounding said at least one penetrative electrode using the conductor film remaining in the second hole.

### BRIEF DESCRIPTION OF THE SEVERAL VIEWS OF THE DRAWING

FIG. 1 is a cross-sectional view schematically showing the structure of a backside illumination CMOS image sensor according to a first embodiment;

FIG. 2 is a top plan view showing a plurality of penetrative electrodes and a guard ring shown in FIG. 1;

FIG. 3 is a cross-sectional view showing the sectional structure of a penetrative electrode shown in FIG. 2 together with a part of a pixel unit;

FIGS. 4A, 4B, 4C, 4D and 4E are cross-sectional views showing the process of manufacturing the CMOS image sensor shown in FIG. 3;

FIG. 5 is a top plan view showing the configuration of a semiconductor device according to a second embodiment; and

FIG. 6 is a top plan view showing the configuration of a semiconductor device according to a third embodiment.

### DETAILED DESCRIPTION OF THE INVENTION

Various embodiments of the present invention will be hereinafter described with reference to the accompanying drawings. In the following drawings, the same reference numerals are used to designate the corresponding portions.

### First Embodiment

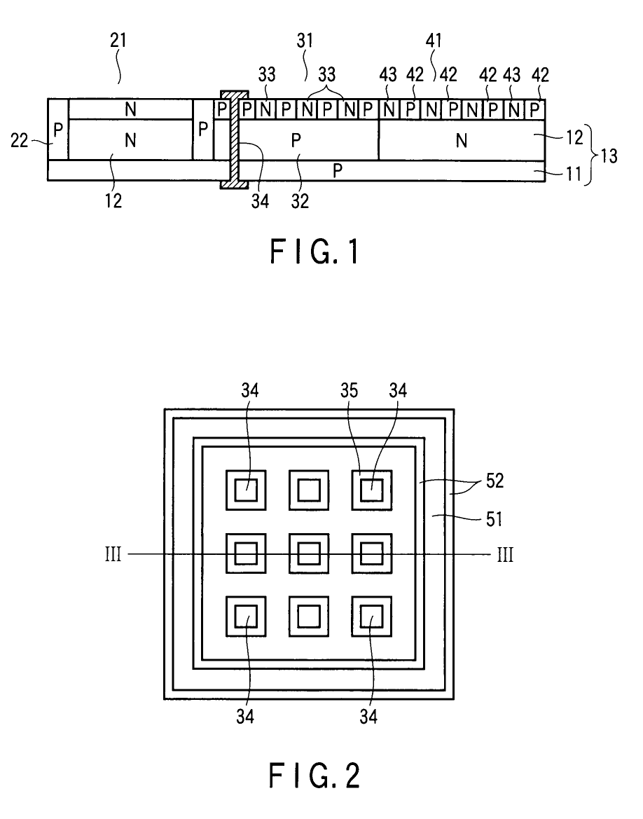

FIG. 1 is a cross-sectional view schematically showing the structure when the present invention is applied to a backside illumination CMOS image sensor. In the CMOS image sensor, a semiconductor substrate 13 comprises a high-density impurity concentration P-type substrate 11 and an N-type epitaxial layer 12 formed thereon. A first region of the semiconductor substrate 13 is formed with a pixel unit 21, and a second region thereof is formed with an analog circuit 31, and further, a third region thereof is formed with a digital circuit 41. The semiconductor substrate 13 is thinned in order to secure light incident on a photodiode (described later) formed in the pixel unit 21, and to prevent optical crosstalk, and to form a plurality of penetrative electrodes. For example, if a silicon substrate has a diameter of 8 inches, the substrate initially having a thickness of 720 μm is thinned to about 5 μm. The rear (second principal face) of the semiconductor substrate 13 is formed with a protective film, interconnects, external terminals and test terminals. The rear of the pixel unit 21 is formed with a color filter pigment, a protective film and a microlens.

The pixel unit 21 is configured so that the surface of the N-type epitaxial layer 12 is formed with an N-type region. The N-type region is formed with a plurality of pixels each having a photodiode and a photodiode select transistor. Further, the pixel unit 21 is formed with a deep P-type well region 22, which extends from the substrate surface (first principal face opposite to the second principal face) to the P-type substrate 11.

The entire surface of the analog circuit 31 is formed with a deep P-type well region 32, which extends from the substrate surface to the P-type substrate 11. The surface of the P-type well region 32 is formed with a plurality of N-type wells 33, which are mutually separated. The P-type well region 32 is formed with a plurality of N-channel MOS transistors. The N-type well region 33 is formed with a plurality of P-channel MOS transistors.

The digital circuit 41 is configured so that the surface of the N-type epitaxial layer 12 is formed with a plurality of P-type well regions 42 and N-type well regions 43. Each P-type well region 42 is formed with a plurality of N-channel MOS transistors. Each N-type well region 43 is formed with a plurality of P-channel MOS transistors.

In the backside illumination CMOS image sensor, incident light from a subject is radiated to an exposed face (rear of semiconductor substrate) of the P-type substrate 11, and not the surface (the surface of the semiconductor substrate 13) of the N-type epitaxial layer 12 of the pixel unit 21. For this reason, the analog circuit 31 and the digital circuit 41 need to have the following structure. Specifically, a plurality of interconnects and/or electrodes formed on the surface and rear of the semiconductor substrate 13 are mutually connected. Further, the rear of the semiconductor substrate 13 is formed with a plurality of external terminals and product test terminals. In order to realize the foregoing structure, the analog circuit 31 and the digital circuit 41 are formed with a plurality of penetrative electrodes 34. The penetrative electrodes 34 penetrate double faces of the semiconductor substrate 13. Further, the penetrative electrodes 34 electrically connect interconnects and/or electrodes. More specifically, the penetrative electrodes 34 connect interconnects and/or electrodes formed on the surface of the semiconductor substrate and interconnects and/or electrodes formed on the rear thereof. Further, the penetrative electrodes 34 connect internal interconnects of analog circuit 31 and the digital circuit 41, product test terminals on the substrate surface and interconnects and/or electrodes formed on the rear of the semiconductor substrate 13. Of course, in FIG. 1, the penetrative electrodes 34 are isolated from the P-type substrate 11 and the P-type well region 32.

The P-type substrate 11 has been connected to ground potential until the semiconductor substrate 13 is thinned. Therefore, ground potential is applied to the analog circuit 31 via the P-well region 32. However, the semiconductor substrate 13 is thinned in order to secure light incident on a photodiode, to prevent optical crosstalk and to form the penetrative electrodes 34. As a result, the P-type substrate 11 is thinner than the conventional case. For this reason, a grounded state with respect to the analog circuit 31 becomes unstable; therefore, the analog circuit 31 is easily influenced by noise from the penetrative electrodes 34 and other circuits.

In order to solve the foregoing problem, the CMOS image sensor of this embodiment is formed with a guard ring 51 as seen from a top plan view of FIG. 2. The guard ring 51 penetrates double faces of the semiconductor substrate 13, and is formed to surround the penetrative electrodes 34. The guard ring 51 is isolated from the semiconductor substrate 13, and connected to ground potential. As shown in FIG. 2, each of the penetrative electrodes 34 shown in FIG. 1 is formed in a state of being divided into several penetrative electrodes (nine in this embodiment). The surroundings of each penetrative electrode 34 are formed with an insulating layer 35. The surroundings of the guard ring 51 is formed with an insulating layer 52. In this case, the guard ring may be formed with respect to one penetrative electrode.

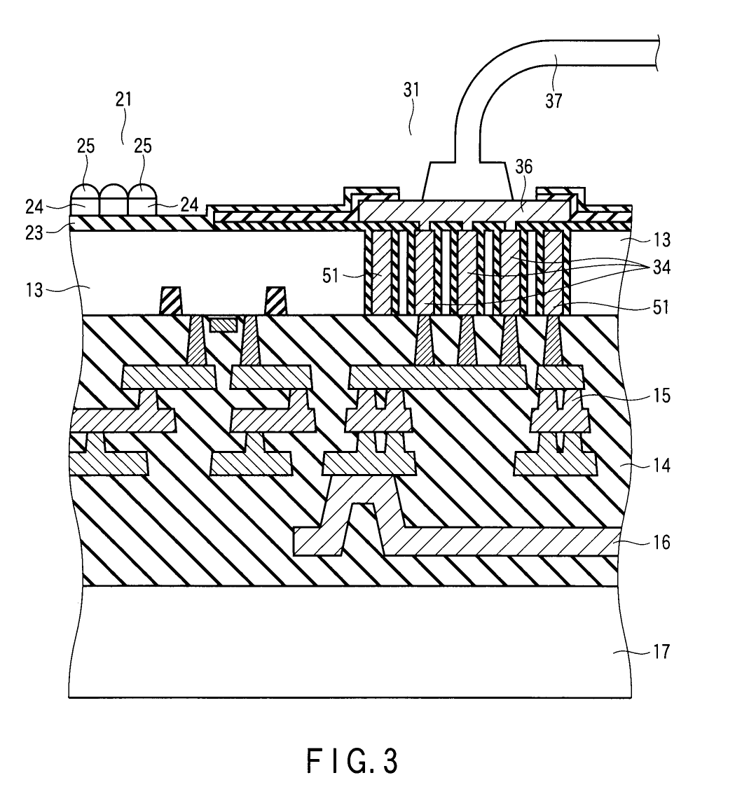

FIG. 3 is a cross-sectional view detailedly showing the sectional structure of the penetrative electrode shown in FIG. 2 together with a part of the pixel unit 21. In the pixel unit 21, an anti-reflection film 23 is formed on the rear of the semiconductor substrate 13. A plurality of color filters 24 for color separation is formed on the anti-reflection film 23. Further, a plurality of microlenses 25 for collecting light is formed on the color filters 24.

A plurality of penetrative electrodes 34 is formed to penetrate double faces of the semiconductor substrate 13. These penetrative electrodes 34 are electrically connected to an external terminal 36, which is formed on the rear of the semiconductor substrate 13. The external terminal 36 is a bonding pad (external electrode), for example. The bonding pad 36 is connected with a metal wire 37. The semiconductor substrate 13 is formed with a guard ring 51, which penetrates double faces of the semiconductor substrate 13. The guard ring 51 surrounds a plurality of penetrative electrodes 34. Further, the guard ring 51 is connected to ground potential by means of a multilayer structure interconnect 15 formed in an interlayer insulating film 14 on the surface side of the semiconductor substrate. According to this embodiment, the guard ring 51 is grounded by means of the foregoing interconnect 15. In this case, an interconnect different from the external interconnect 36 may be formed and grounded. The penetrative electrodes 34 are electrically connected to other interconnects formed on the surface of the semiconductor substrate 13 by means of the multilayer structure interconnect 16 formed in the interlayer insulating film 14. The interlayer insulating film 14 is attached with a support substrate 17 because the substrate 13 is thinned. Each thickness of the first to third regions of the semiconductor substrate 13 is equal.

In the CMOS image sensor having the foregoing structure, the guard ring 51 is formed to surround a plurality of penetrative electrodes 34, and connected to ground potential. Therefore, this serves to reduce the influence of noise from the penetrative electrode 34.

This embodiment relates to the case where the penetrative electrode 34 is formed in a state of being divided into several portions in the semiconductor substrate 13. In this case, the penetrative electrode 34 is not necessarily formed in a state of being divided into several portions. The penetrative electrode 34 may be formed at one portion. However, as can be seen from FIG. 3, it is effective to form the penetrative electrode 34 in a state of being divided into several portions in order to secure sufficient current capacitance when the electrode 34 is connected to the external terminal 36. Moreover, this embodiment relates to the case where the guard ring 51 is connected to ground potential. In this case, the guard ring 51 may be connected to optional voltages other than ground, or may be set to a potentially floating state without being connected to any potentials and voltages.

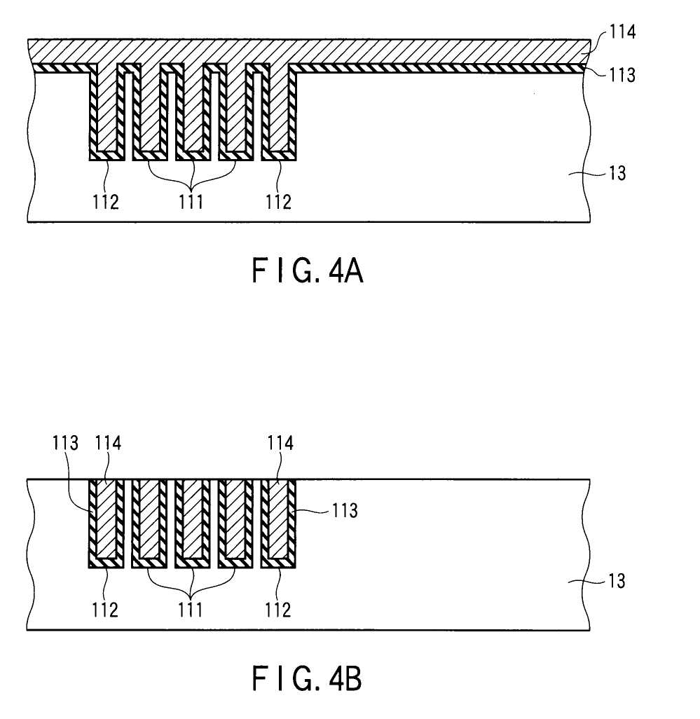

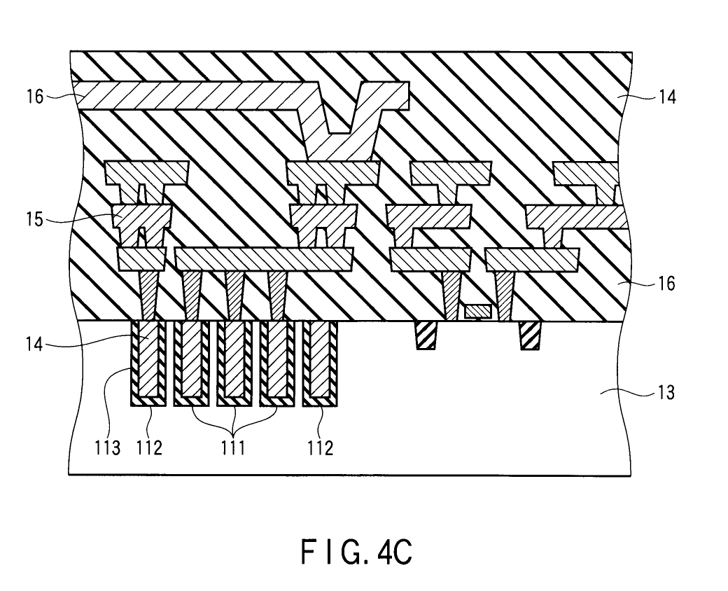

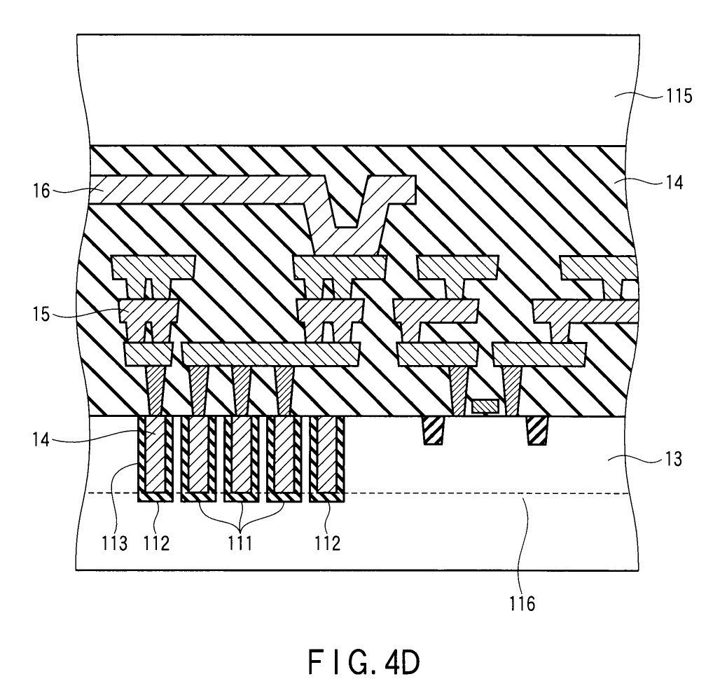

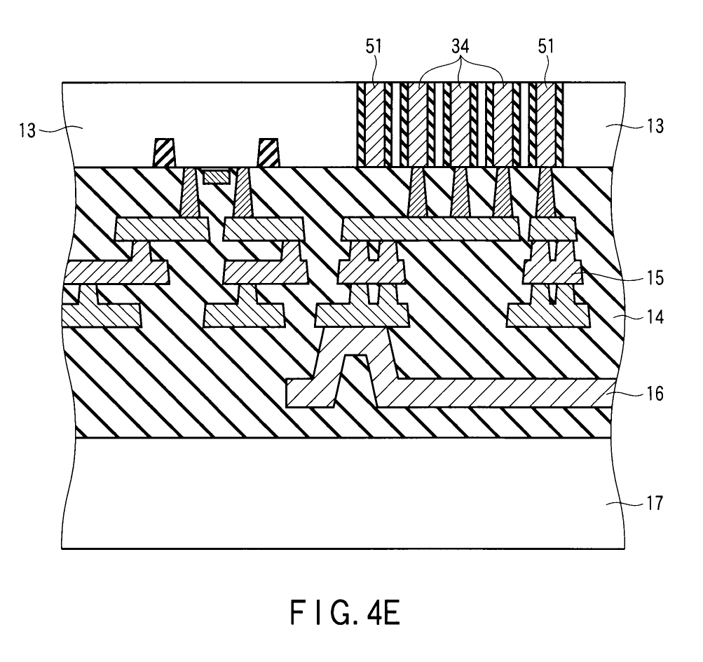

A method of manufacturing the CMOS image sensor of FIG. 3 will be described below. As shown in FIG. 4A, a plurality of first holes 111 and a second hole 112 surrounding these first holes 111 are formed having a depth, which does not reach the rear of the semiconductor substrate 13 from the surface thereof. Thereafter, an insulating film, for example, a silicon oxide film 113 is deposited on the entire surface with a thickness, which does not fill first and second holes 111 and 112. A conductor film 114 including metal or polysilicon is formed on the entire surface with a thickness such that first and second holes 111 and 112 are filled with the conductor film 114. As illustrated in FIG. 4B, the conductor film 114 and the silicon oxide film 113 are removed using chemical mechanical polishing (CMP) or reactive ion etching (RIE) so that the surface of the substrate 13 is exposed.

The surface of the semiconductor substrate 13 is formed with pixels including a transistor and a photodiode. Thereafter, as depicted in FIG. 4C, the following interconnects are formed by depositing an interlayer insulating film 14 and a conductor material and by patterning the conductor material. One is a multilayer structure interconnect 16 for electrically connecting the conductor film 114 remaining in the first hole 111. The other is a multilayer structure interconnect 15 for electrically connecting the conductor film 114 remaining in the second hole 112. As seen from FIG. 4D, plasma treatment is carried out with respect to the surface of the interlayer insulating film 14. Thereafter, a silicon support substrate 115 is bonded onto the interlayer insulating film 14 by a sticking technique using covalent bond.

The semiconductor substrate 13 is polished or etched from the rear, and then, thinned by the portion shown by the broken line 116 in FIG. 4D. The foregoing polishing is carried out, and thereby, as shown in FIG. 4E, each surface of conductor films 114 remaining in first and second holes 111 and 112 is exposed. In this way, a plurality of penetrative electrodes 34 are formed out of the conductor film 114 remaining in the first hole 111 while a guard ring surrounding the penetrative electrode 34 is formed out of the conductor film 114 remaining in the second hole 112. Thereafter, as described in FIG. 3, in the pixel unit 21, an anti-reflection film 23 is formed on the rear of the semiconductor substrate 13. Further, a plurality of color filters 24 are formed on the antireflection film. Furthermore, a plurality of microlenses 25 is formed on the color filters 24. In the region other than the pixel unit 21, an insulating film is deposited. A plurality of contact holes are formed in the insulating film for connecting the penetrative electrodes 34. The rear of the semiconductor substrate 13 is formed with a bonding pad 36. A metal wire 37 is connected to the bonding pad 36.

### Second Embodiment

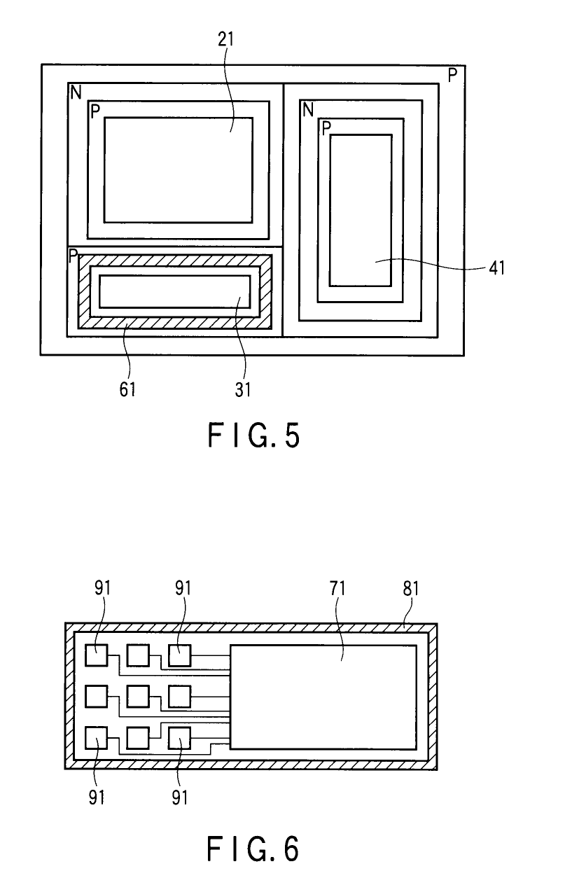

FIG. 5 is a top plan view showing the configuration of a semiconductor device according to a second embodiment. The semiconductor device is realized by applying the present invention to a CMOS image sensor including a pixel unit 21, an analog circuit 31 and a digital circuit 41 integrated on a semiconductor substrate, as well as the first embodiment. In a CMOS image sensor of this embodiment, a guard ring 61 is formed to have a shape surrounding the analog circuit 31 and to penetrate double faces of the semiconductor substrate. The guard ring 61 is isolated from the semiconductor substrate, and connected to ground potential.

As described above, the whole of the analog circuit 31 is surrounded with the guard ring 61. In this way, it is possible to prevent noise generated in the analog circuit 31 from externally leaking, and to prevent externally generated noise from entering the analog circuit 31. As a result, the influence of noise is reduced using the guard ring 61.

This embodiment relates to the case where the guard ring 61 is connected to ground potential. In this case, the guard ring 61 may be connected to optional voltages other than ground, or may be set to a potentially floating state without being connected to any potentials and voltages.

### Third Embodiment

A semiconductor device, in particular, in an internal circuit formed with a relatively large-sized transistor such as an input/output (I/O) circuit of an integrated circuit has the following problem. Namely, considerable noise is generated with switching operations of transistors. In order to solve the foregoing problem, a semiconductor device according to a third embodiment is formed with a guard ring 81 in the following manner. Specifically, as shown in a top plan view of FIG. 6, the guard ring 81 is formed to surround an I/O circuit 71 of an integrated circuit formed on a semiconductor substrate, and to penetrate double faces of the semiconductor substrate. The guard ring 81 is isolated from the semiconductor substrate, and connected to ground potential. In this case, a plurality of electrode pads 91, which are electrically connected to the I/O circuit 71 and inputs/outputs a signal, is surrounded by the guard ring 81.

According to this embodiment, the I/O circuit 71 is surrounded by the guard ring 81, and thereby, it is possible to prevent noise generated in the I/O circuit 71 from externally leaking. As a result, the influence of noise is reduced using the guard ring 81.

This embodiment relates to the case where the guard ring 81 is connected to ground potential. In this case, the guard ring 81 may be connected to optional voltages other than ground, or may be set to a potentially floating state without being connected to any potentials and voltages.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A backside illumination solid-state imaging device comprising:
a semiconductor substrate having a first principal face and a second principal face opposite thereto, and including a pixel unit formed in a first region, an analog circuit formed in a second region and a digital circuit formed in a third region;
an interconnect formed on each of the first and second principal faces of the semiconductor substrate;
at least one penetrative electrode formed in the semiconductor substrate to penetrate the first and second principal faces, and electrically connecting the interconnects formed in the first and second principal faces of the semiconductor substrate; and
a guard ring formed in the semiconductor substrate to penetrate the first and second principal faces, and surrounding said at least one penetrative electrode.

2. The device according to claim 1, wherein a plurality of microlenses is formed on the second principal face of the first region.

3. The device according to claim 1, wherein said at least one penetrative electrode is formed on the second region of the semiconductor substrate.

4. The device according to claim 1, wherein said at least one penetrative electrode is formed several.

5. The device according to claim 1, wherein the guard ring is formed on the second region.

6. The device according to claim 1, wherein an optional potential including ground potential is applied to the guard ring.

7. The device according to claim 1, wherein the guard ring is set to a potentially floating state.

8. The device according to claim 1, wherein the first region of the semiconductor substrate has the same thickness as the second region thereof.

9. The device according to claim 1, wherein the interconnect formed on the second principal face is a bonding pad.

10. A method of manufacturing a backside illumination solid-state imaging device, comprising:
forming at least one first hole and a second hole with a depth in a semiconductor substrate, the semiconductor substrate has a first principal face and a second principal face opposite thereto, said at least one first hole is surrounded by the second hole, the depth does not reach the second principal face from the first principal face;
depositing a first insulating film on the entire surface with a thickness that said at least one first hole and the second hole are not filled with the first insulating film;
forming a conductor film on the entire surface with a thickness that at least one first hole and the second hole are not filled with the conductor film;
removing the conductor film and the first insulating film to expose the first principal face;
forming a first interconnect electrically connecting the conductor film remaining in said at least one first hole while forming a second interconnect the conductor film remaining in the second hole on the first principal face; and
polishing the semiconductor substrate from the second principal face to expose each surface of the conductor film remaining in said at least one first hole and the conductor film remaining in the second hole, and forming at least one penetrative electrode using the conductor film remaining in said at least one first hole while forming a guard ring surrounding said at least one penetrative electrode using the conductor film remaining in the second hole.

11. The method according to claim 10, wherein said at least one first hole is a plurality of holes.

12. The method according to claim 10, further comprising:
forming a third interconnect electrically connecting said at least one penetrative electrode on the second principal face.

13. A semiconductor device comprising:
a semiconductor substrate having a first principal face and a second principal face opposite thereto, and formed with an integrated circuit;
an interconnect and/or electrode formed on each of the first and second principal faces;
a penetrative electrode formed in the semiconductor substrate in a state of penetrating the first and second principal faces, and electrically connecting interconnects and/or electrodes formed on each of the first and second principal faces; and
a guard ring formed in the semiconductor substrate in a state of penetrating the first and second principal faces, and surrounding the penetrative electrode.

14. The device according to claim 13, wherein an optional potential including ground potential is applied to the guard ring.

15. The device according to claim 13, wherein the guard ring is set to a potentially floating state.
